(19) United States
(12) Patent Application Publication
(10) Pub. No.: US 2026/0125790 A1
(43) Pub. Date: May 7, 2026

(54) CONTROLLING ARCING WITH SEASON

(71) Applicant: Applied Materials, Inc., Santa Clara, CA (US)

(72) Inventors: Allison Yau, Mountain View, CA (US); Shichen Fu, Santa Clara, CA (US); Manoj Kumar Jana, San Jose, CA (US); Zhiling Dun, Campbell, CA (US); Hang Yu, San Jose, CA (US); Deenesh Padhi, Saratoga, CA (US)

(73) Assignee: Applied Materials, Inc., Santa Clara, CA (US)

(21) Appl. No.: 18/938,172

(22) Filed: Nov. 5, 2024

(51) Int. Cl. C23C 16/40; C23C 16/34; C23C 16/458; H01L 21/683

(52) U.S. Cl. CPC C23C 16/401; C23C 16/34; C23C 16/4586; H10P 72/722

(57) ABSTRACT

Methods of season chamber components, methods of processing substrates, and seasoned chamber components are provided. Methods include flowing one or more deposition precursors at a deposition temperature into a substrate processing region of a semiconductor processing chamber housing the semiconductor processing chamber component. Methods include where the substrate processing region includes an electrostatic chuck, and the one or more deposition precursors are generally free of a nitride precursor. Methods include depositing at least a first seasoning layer on the semiconductor processing chamber component, where the at least the first seasoning layer has a thickness of greater than 0.5 μm.

### TECHNICAL FIELD

The present technology relates to semiconductor systems, processes, and equipment. More specifically, the present technology relates to systems and methods for seasoning semiconductor processing components.

### BACKGROUND

Integrated circuits are made possible by processes which produce intricately patterned material layers on substrate surfaces. Producing patterned material on a substrate requires controlled methods for forming and removing material. Some processes to make integrated circuits include the deposition of many layers on a substrate. In some instances, the cumulative stresses generated by the increasing number of layers can create stresses that are large enough to warp the substrate during fabrication. The substrate warping, also referred to as bowing, can have many adverse effects on circuit fabrication, including the formation of layers with an uneven thickness across the substrate surface.

Electrostatic chucks are utilized to reduce bowing during processing. However, existing electrostatic chucks either fail to fully flatten a bowed substrate or exhibit unacceptable arcing during processing. Thus, there is a need for improved systems and methods which can be used to produce high quality devices and structures with reduced arcing during semiconductor processing.

### SUMMARY

The present disclosure is generally directed to methods of seasoning semiconductor processing chamber components, as well as seasoned processing chamber components. Methods include flowing one or more deposition precursors at a deposition temperature into a substrate processing region of a semiconductor processing chamber housing the semiconductor processing chamber component, where the substrate processing region includes an electrostatic chuck, and the one or more deposition precursors are generally free of a nitride precursor. Methods include depositing at least a first seasoning layer on the semiconductor processing chamber component, where the at least the first seasoning layer comprises a thickness of greater than 0.5 μm.

In embodiments, methods include where the semiconductor processing chamber component includes an electrostatic chuck. Furthermore, in embodiments, the one or more deposition precursors include a silicon-containing precursor, the silicon-containing precursor comprising silane (SiH4), disilane (Si2H6), trisilane (Si3H8), silicon tetrachloride (SiCl4), tetraethyl orthosilicate (TEOS), or combinations thereof. In more embodiments, the one or more deposition precursors includes an oxygen-containing precursor, the oxygen containing precursor including molecular oxygen (O2), ozone (O3), or combinations thereof. Additionally or alternatively, in embodiments, the one or more deposition precursors include tetraethyl orthosilicate and molecular oxygen. In embodiments, one or more deposition precursors includes a silicon-containing precursor and an oxygen-containing precursor, where a ratio of the oxygen-containing precursor to the silicon-containing precursor is greater than or about 1:1. Moreover, in embodiments, the at least a first seasoning layer includes silicon oxide, and exhibits a thickness greater than or about 1 micrometer. In further embodiments, the seasoning layer includes a thickness greater than or about 3.6 micrometers. In embodiments, the deposition temperature is greater than or about 350° C. In yet more embodiments, the deposition temperature is greater than 550° C.

The present technology is also generally directed to substrate support assemblies. Assemblies include an electrostatic chuck, where at least a portion of the electrostatic chuck comprises a seasoning layer. Assemblies include a support stem coupled to the electrostatic chuck, and an electrode embedded within the electrostatic chuck between a substrate support surface and the support stem. Assemblies include where the seasoning layer has a thickness greater than 0.5 micrometers and is free of nitride or nitride containing materials.

In embodiments, the seasoning layer comprises silicon oxide and exhibits a thickness greater than or about 1 micrometer. Moreover, in embodiments, the seasoning layer has a thickness greater than or about 3.6 micrometers. In further embodiments, the support substrate further includes a heater embedded within the electrostatic chuck. Embodiments include where the seasoning layer exhibits a modulus of greater than or about 50 GPA, a hardness of greater than or about 5 GPA, less than 1 wt. % impurities, or a combination thereof.

The present technology is also generally directed to semiconductor processing methods. Methods include contacting a semiconductor substrate with an electrostatic chuck in a substrate processing region of a semiconductor processing chamber, where the electrostatic chuck has been seasoned with a seasoning layer, where the seasoning layer is generally free of nitride or nitride containing materials. Methods include applying a chucking voltage to the semiconductor substrate of greater than or about 1.2 kV, and depositing two or more layers on the chucked substrate, wherein the greater than two layers comprises one or more alternating pairs of oxide and nitride material. In embodiments, the two or more layers include an oxide-nitride (ON) stack. Additionally or alternatively, in embodiments, the two or more layers include greater than or about 100 layers. Furthermore, in embodiments, the chucking voltage is greater than or about 1.4 kV. In embodiments, the seasoning layer includes a modulus of greater than or about 50 GPA, a hardness of greater than or about 5 GPA, less than 1 wt. % impurities, or a combination thereof.

Such technology may provide numerous benefits over conventional systems and techniques. For example, embodiments of the present technology may provide substrate supports with increased electrostatic chucking forces to counter a substrate bow, with reduced or eliminated instances of arcing. Additionally, by providing reduced leakage currents relative to conventional technologies, an increased chucking voltage may be afforded without the electrostatic chuck damaging the substrate or processing chamber, even at high temperature processing. These and other embodiments, along with many of their advantages and features, are described in more detail in conjunction with the below description and attached figures.

### BRIEF DESCRIPTION OF THE FIGURES

A further understanding of the nature and advantages of the disclosed technology may be realized by reference to the remaining portions of the specification and the drawings.

FIG. 1 shows a top plan view of an exemplary processing system according to embodiments of the present technology.

FIG. 2 shows a schematic cross-sectional view of an exemplary plasma system according to embodiments of the present technology.

FIG. 3 shows a schematic partial cross-sectional view of an exemplary substrate support assembly according to embodiments of the present technology.

FIG. 4 shows selected operations in processing methods according to embodiments of the present technology.

FIG. 5A shows a schematic partial cross-sectional view of an exemplary semiconductor processing component according to embodiments of the present technology.

FIG. 5B shows a schematic partial cross-sectional view of an exemplary semiconductor processing component according to embodiments of the present technology.

FIG. 5C shows a schematic partial cross-sectional view of an exemplary semiconductor processing component according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. These formed films may be produced under conditions that cause stresses on the substrate. For example, in the development of dielectric layers for vertical memory applications, such as oxide-nitride (ON) or oxide-polysilicon (OP) stacks, many layers of material may be deposited on a substrate. These produced films may be characterized by internal stresses that act upon the substrate. This may cause a substrate to warp or bow during processing, which can lead to poor uniformity during film formation, as well as device damage or malfunction.

Electrostatic chucking may be utilized to chuck a substrate to a substrate support during processing and to improve any bowing present on the substrate. However, bowed, particularly highly bowed substrates, necessitate the need for increased chucking voltages. As these device stacks increase in numbers of layers, the stresses acted upon the substrate increase, which may require a proportional increase in chucking voltage. At elevated temperature, the substrate material of the electrostatic chuck exhibits increased leakage current. The increased leakage current reduces the ability of the chuck to maintain the high electrostatic forces needed to offset the forces on the substrate that reduce bowing. When the leakage current reaches an unacceptable level, the electrostatic chuck cannot generate enough electrostatic force to prevent the substrate from bowing during a multilayer film deposition.

One cause of leakage current in electrostatic chucks is the electrical properties of the seasoning film or layer that covers the exposed surfaces of the electrostatic chuck. Conventional seasoning films include a bilayer of silicon oxide and silicon nitride deposited on the surfaces of the electrostatic chuck. However, the silicon nitride contained in the coating, in particular, exhibits electrical instability, forming charge traps that instigate unstable breakdown thresholds and random discharging. The nitride is included in conventional seasoning layers to prevent metal diffusion from the electrostatic chuck into the chamber during processing, as metal diffusion can damage the substrate during processing, and may also degrade the electrostatic chuck over time. As chucking voltage increases, electrical instability due at least in part to charge traps formed by the nitride can lead to arcing and ultimately damage to the substrate from the arcs, as well as the diminished ability to properly chuck the substrate. However, thus far, oxide seasoning without the presence of the nitride bilayer has been unable to prevent metal diffusion during processing. These issues have also limited technologies that require higher chucking voltages or high temperature processing, as leakage current further increases with increased temperature, and have limited the ability to increase the number of layers deposited on a substrate, due to the inability to address high levels of bowing.

Breakdown voltage is the minimum voltage that causes a portion of an insulator to become electrically conductive. In semiconductor processing, it is the voltage at which the insulating material (such as the dielectric layer in a semiconductor device) breaks down and becomes conductive. When the voltage applied across a semiconductor material or between components exceeds the breakdown voltage, the electric field becomes strong enough to ionize the surrounding medium (air, gas, or the semiconductor material itself). This ionization leads to an electrical discharge or arc. Maintaining voltages below the breakdown threshold is therefore necessary to prevent arcing.

The present technology overcomes these and other challenges by carefully coating, also referred to as “seasoning”, one or more components of the semiconductor processing chamber, such as an electrostatic chuck. Namely, the present technology has surprisingly found that by carefully forming a robust and highly consistent seasoning layer, leakage current and arcing is drastically reduced compared to conventional technologies. The present technology also affords a reduced electrostatic charge buildup compared to other seasoning layers that further allow an increase in chucking voltage with reduced arcing and subsequent damage to a substrate, even at elevated temperatures. Thus, the present technology may provide substrate support assemblies having uniquely formed seasoning or coating layer(s) that exhibit specifically tailored electrical characteristics that may increase breakdown strength and reduce electrostatic charge buildup over conventional technologies, particularly at increased chucking voltages.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include pedestals according to embodiments of the present technology before additional variations and adjustments to this system according to embodiments of the present technology are described.

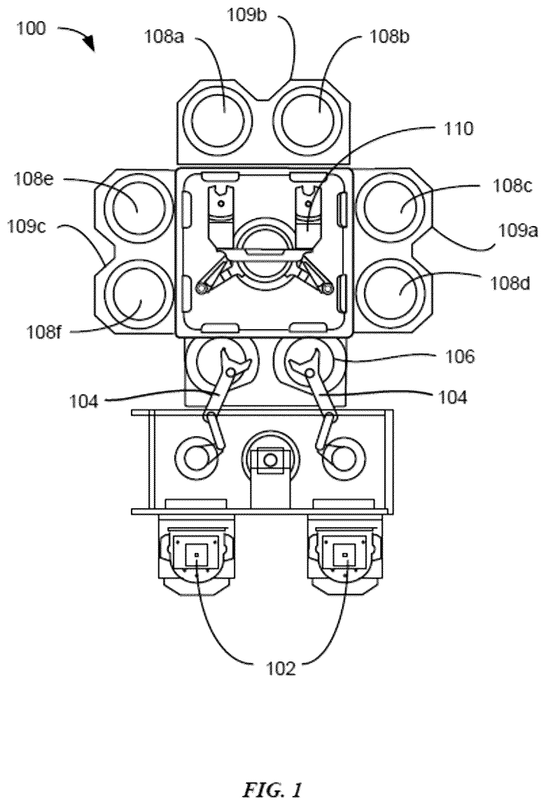

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate substrates from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

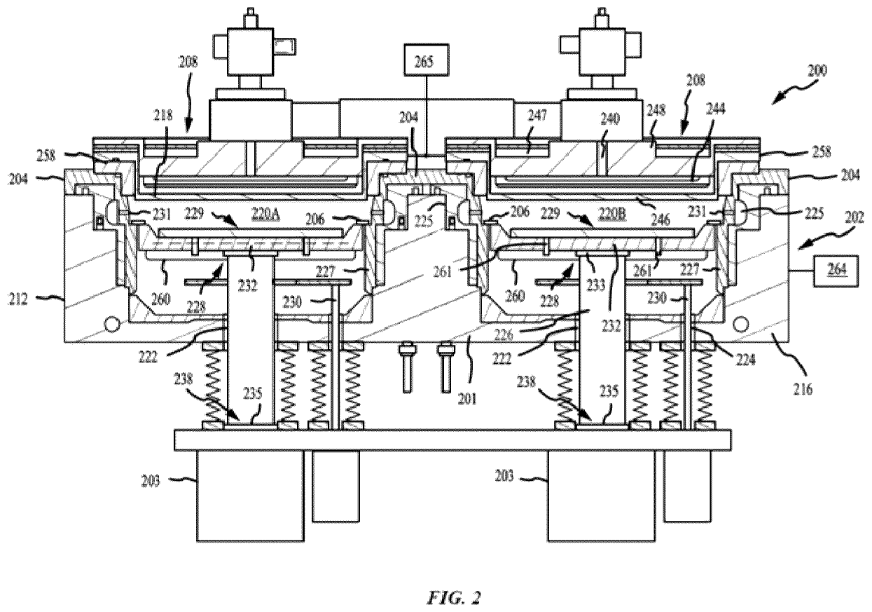

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include substrate support assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the gas distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

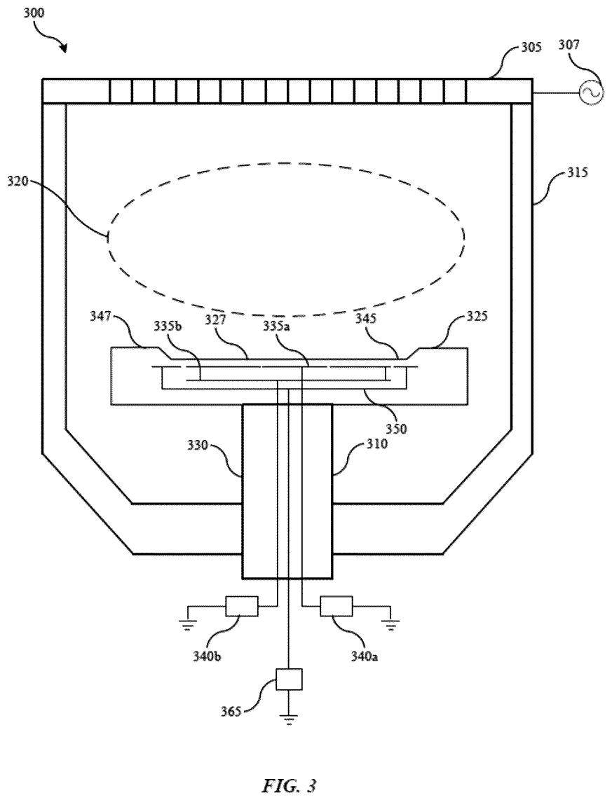

FIG. 3 shows a schematic partial cross-sectional view of an exemplary semiconductor processing chamber 300 according to some embodiments of the present technology. FIG. 3 may include one or more components discussed above with regard to FIG. 2 and may illustrate further details relating to that chamber. The chamber 300 may be used to perform semiconductor processing operations including deposition of stacks of dielectric materials as previously described. Chamber 300 may show a partial view of a processing region of a semiconductor processing system, and may not include all of the components, such as additional lid stack components previously described, which are understood to be incorporated in some embodiments of chamber 300.

As noted, FIG. 3 may illustrate a portion of a processing chamber 300. The chamber 300 may include a showerhead 305, as well as a substrate support assembly 310. Along with chamber sidewalls 315, the showerhead 305 and the substrate support 310 may define a substrate processing region 320 in which plasma may be generated. The substrate support assembly may include an electrostatic chuck body 325, which may include one or more components embedded or disposed within the body. The components incorporated within the top puck may not be exposed to processing materials in some embodiments and may be fully retained within the chuck body 325. Electrostatic chuck body 325 may define a substrate support surface 327 and may be characterized by a thickness and length or diameter depending on the specific geometry of the chuck body. In some embodiments, the chuck body may be elliptical and may be characterized by one or more radial dimensions from a central axis through the chuck body. It is to be understood that the top puck may be any geometry, and when radial dimensions are discussed, they may define any length from a central position of the chuck body.

Electrostatic chuck body 325 may be coupled with a stem 330, which may support the chuck body and may include channels for delivering and receiving electrical and/or fluid lines that may couple with internal components of the chuck body 325. Chuck body 325 may include associated channels or components to operate as an electrostatic chuck, although in some embodiments the assembly may operate as or include components for a vacuum chuck, or any other type of chucking system. Stem 330 may be coupled with the chuck body on a second surface of the chuck body opposite the substrate support surface. The electrostatic chuck body 325 may include a first bipolar electrode 335a, which may be embedded within the chuck body proximate the substrate support surface. Electrode 335a may be electrically coupled with a DC power source 340a which may also include an RF power source. Power source 340a may be configured to provide energy or voltage to the electrically conductive chuck electrode 335a. For example, electrode 335a may be a chucking mesh that operates as an electrical ground for a capacitive plasma system including an RF source 307 electrically coupled with showerhead 305. In embodiments, electrode 335a may operate as a ground path for RF power from the RF source 307, while also operating as an electric bias to the substrate to provide electrostatic clamping of the substrate to the substrate support surface. Power source 340a may include a filter, a power supply, and a number of other electrical components configured to provide a chucking voltage.

The electrostatic chuck body may also include a second bipolar electrode 335b, which may also be embedded within the chuck body proximate the substrate support surface. Electrode 335b may be electrically coupled with a DC power source 340b which may also include an RF power source. Power source 340b may be configured to provide energy or voltage to the electrically conductive chuck electrode 335b. Electrode 335b may additionally or in alternative to electrode 335a, be a chucking mesh that operates as an electrical ground for a capacitive plasma system including an RF source 307 electrically coupled with showerhead 305. In embodiments, electrode 335b may additionally or in alternative to electrode 335a, operate as a ground path for RF power from the RF source 307, while also operating as an electric bias to the substrate to provide electrostatic clamping of the substrate to the substrate support surface. Power source 340b may include a filter, a power supply, and a number of other electrical components configured to provide a chucking voltage.

Furthermore, as will be discussed in greater detail below, electrostatic chucks according to the present technology may also include a third electrode 350, which may also be embedded within the chuck body proximate the substrate surface. However, electrode 350 may not be in contact with a DC power source and may instead only be coupled with a RF power source 365. Power source 365 may be configured to provide energy to the third electrode 350. Electrode 350 may additionally or in alternative to electrode 335a and/or 335b be a chucking mesh that operates as an electrical ground for a capacitive plasma system including an RF source 307 electrically coupled with showerhead 305. In embodiments, electrode 350 may additionally or in alternative to electrode 335a and/or 335b, operate as a ground path for RF power from the RF source 307, while also operating as an electric bias to the substrate to provide electrostatic clamping of the substrate to the substrate support surface. Power source 340b may include a filter, a power supply, and a number of other electrical components configured to provide a chucking voltage. Additionally electrical components and details about bipolar chucks according to some embodiments will be described further below, and any of the designs may be implemented with processing chamber 300. For example, additional plasma related power supplies or components may be incorporated as will be explained further below.

In operation, a substrate may be in at least partial contact with the substrate support surface of the electrostatic chuck body, which may produce a contact gap, and which may essentially produce a capacitive effect between a surface of the pedestal and the substrate. Voltage may be applied to the contact gap, which may generate an electrostatic force for chucking. The power supplies 340a and 340b may provide electric charge that migrates from the electrode to the substrate support surface where it may accumulate, and which may produce a charge layer having Coulomb attraction with opposite charges at the substrate, and which may electrostatically hold the substrate against the substrate support surface of the chuck body. This charge migration may occur by current flowing through a dielectric material of the chuck body based on a finite resistance within the dielectric for Johnsen-Rahbek type chucking, which may be used in some embodiments of the present technology.

Chuck body 325 may also define a recessed region 345 within the substrate support surface, which may provide a recessed pocket in which a substrate may be disposed. Recessed region 345 may be formed at an interior region of the top puck and may be configured to receive a substrate for processing. Recessed region 345 may encompass a central region of the electrostatic chuck body as illustrated and may be sized to accommodate any variety of substrate sizes. However, as discussed above, it should be clear that, in embodiments the substrate support may be generally planar, and may not include a recessed region 345. A substrate may be seated within the recessed region, and contained by an exterior region 347, which may encompass the substrate. In some embodiments the height of exterior region 347 may be such that a substrate is level with or recessed below a surface height of the substrate support surface at exterior region 347. A recessed surface may control edge effects during processing, which may improve uniformity of deposition across the substrate in some embodiments. In some embodiments, an edge ring may be disposed about a periphery of the top puck and may at least partially define the recess within which a substrate may be seated. In some embodiments, the surface of the chuck body may be substantially planar, and the edge ring may fully define the recess within which the substrate may be seated.

In some embodiments the electrostatic chuck body 325 and/or the stem 330 may be insulative or dielectric materials. For example, oxides, nitrides, carbides, and other materials may be used to form the components. Exemplary materials may include ceramics, including aluminum oxide, aluminum nitride, silicon carbide, tungsten carbide, and any other metal or transition metal oxide, nitride, carbide, boride, or titanate, as well as combinations of these materials and other insulative or dielectric materials. Different grades of ceramic materials may be used to provide composites configured to operate at particular temperature ranges, and thus different ceramic grades of similar materials may be used for the top puck and stem in some embodiments. Dopants may be incorporated in some embodiments to adjust electrical properties as well. Exemplary dopant materials may include yttrium, magnesium, silicon, iron, calcium, chromium, sodium, nickel, copper, zinc, or any number of other elements known to be incorporated within a ceramic or dielectric material.

Electrostatic chuck body 325 may also include an embedded heater contained within the chuck body. In some embodiments the electrode 335a and/or 335b may be operated as the heater, but by decoupling these operations, more individual control may be afforded, and extended heater coverage may be provided while limiting the region for plasma formation. Nonetheless, a heater may include multiple heaters in embodiments, and each heater may be associated with a zone of the chuck body, and thus exemplary chuck bodies may include a similar number or greater number of zones than heaters.

A heater, when utilized may be capable of adjusting temperatures across the electrostatic chuck body 325, as well as a substrate residing on the substrate support surface 327. The heater may have a range of operating temperatures to heat the chuck body and/or a substrate above or about 100° C., and the heater may be configured to heat above or about 125° C., above or about 150° C., above or about 175° C., above or about 200° C., above or about 250° C., above or about 300° C., above or about 350° C., above or about 400° C., above or about 450° C., above or about 500° C., above or about 550° C., above or about 600° C., above or about 650° C., above or about 700° C., above or about 750° C., above or about 800° C., above or about 850° C., above or about 900° C., above or about 950° C., above or about 1000° C., or higher. The heater may also be configured to operate in any range encompassed between any two of these stated numbers, or smaller ranges encompassed within any of these ranges. In some embodiments, the chuck heater may be operated to maintain a substrate temperature above at least 500° C. during deposition operations.

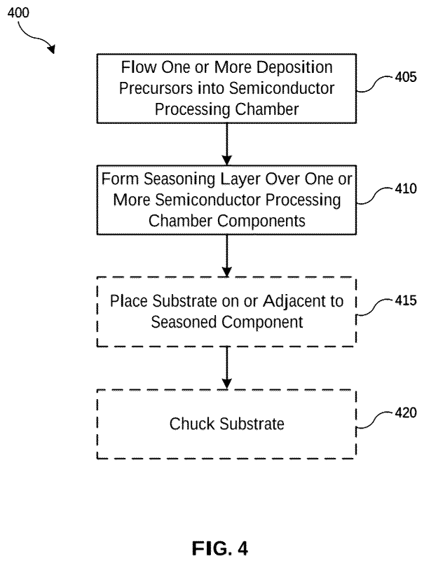

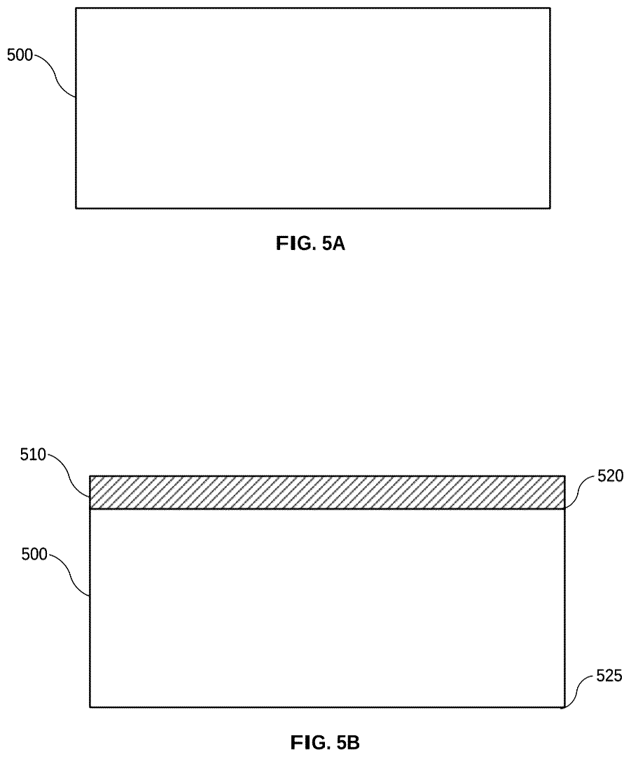

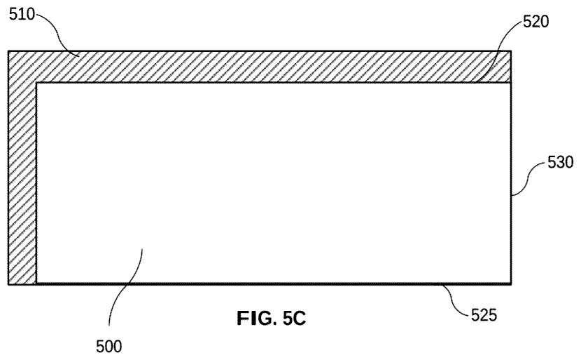

FIG. 4 shows exemplary operations in a processing method 400 according to some embodiments of the present technology. The method may be performed in a variety of processing chambers, including processing chamber 100, 200, and/or 300 described above, as well as any other chambers in which the operations may be performed. Method 400 may include one or more operations prior to the initiation of the method, including front-end processing, deposition, etching, polishing, cleaning, or any other operations that may be performed prior to the described operations. The methods may include a number of optional operations, which may or may not be specifically associated with some embodiments of methods according to embodiments of the present technology. For example, many of the operations are described in order to provide a broader scope of the processes performed, but are not critical to the technology, or may be performed by alternative methodology as will be discussed further below. Method 400 may describe operations shown schematically in FIGS. 5A-5C, the illustrations of which will be described in conjunction with the operations of method 400. It is to be understood that the figures illustrate only partial schematic views, and a substrate may contain any number of additional materials and features having a variety of characteristics and aspects as illustrated in the figures. Additionally, it is to be understood that the figures illustrate just one exemplary process in which molecular layer deposition according to embodiments of the present technology may be employed, and the description is not intended to limit the technology to this process alone.

FIG. 4 illustrates selected operations in processing methods 400 according to embodiments of the present technology. Embodiments of the present technology include processing methods for forming a seasoning layer on exposed surfaces of a semiconductor processing component, such as component 500 illustrated in FIG. 5A. The methods may include a number of optional operations, which may or may not be specifically associated with some embodiments of methods according to the present technology. One or more operations may also be performed before or after the present methods. For example, a cleaning operation may be performed in the semiconductor processing chamber before the seasoning layer is formed on exposed surfaces of the component surfaces in the processing chamber. In some instances, the cleaning operation may include flowing an etchant gas such as NF₃ into the processing chamber to remove materials deposited in or on one or more components and/or the chamber walls during previous deposition operations. In further instances, the cleaning operation may leave behind cleaning residues on one or more exposed surfaces of the chamber walls that may be covered by the seasoning layer.

In embodiments, the process 400 may begin by flowing one or more deposition precursors into a semiconductor processing chamber at operation 405. In embodiments, the one or more deposition precursors flowed into the semiconductor processing chamber may include an oxygen-containing precursor and a silicon-containing precursor. In embodiments, silicon-containing precursor may be or include silane (SiH₄), disilane (Si₂H₆), trisilane (Si₃H₈), silicon tetrachloride (SiCl₄), tetraethyl orthosilicate (TEOS), or any other precursor able to form a silicon-containing material such as, for example, a silicon oxide (SiO) material. Although higher-order silanes may be used in embodiments of the present technology, the increased hydrogen content in the material as deposited may lead to outgassing in subsequent operations. Thus, in embodiments, the silicon-containing precursor may be or include tetraethyl orthosilicate (TEOS). In embodiments, the oxygen containing precursor may be or include any oxygen-containing precursor such as, for example, molecular oxygen (O2), ozone (O3), or combinations thereof. In embodiments, it may be desired to utilize molecular oxygen, as the oxygen-containing precursor.

In embodiments, the precursors provided at operation 405 may also include any number of carrier gases, which may include nitrogen, helium, argon, or other noble, inert, or useful precursors. The carrier gases may be used to dilute the silicon-containing precursor or the oxygen-containing precursor, which may reduce deposition rates to allow adequate control of the deposition. However, it is contemplated that the precursors may be provided without any other gases.

Regardless of the precursors selected, in embodiments, the one or more seasoning layers may be generally free of nitride or nitride containing materials. For instance, in embodiments, each seasoning layer or all of the seasoning layers may contain less than or about 5 wt. % nitride or nitride containing materials, such as less than or about 4.5 wt. %, less than or about 4 wt. %, less than or about 3.5 wt. %, less than or about 3 wt. %, less than or about 2.5 wt. %, less than or about 2 wt. %, less than or about 1.5 wt. %, less than or about 1 wt. %, less than or about 0.5 wt. %, less than or about 0.25 wt. %, less than or about 0.1 wt. %, less than or about 0.01 wt. %, or less, such as free of nitride or nitride containing materials. Thus, in embodiments, the one or more seasoning layers of the present technology may be considered to be a monolayer of silicon oxide.

In embodiments, the present technology has surprisingly found that a quality of the seasoning layer, and therefore the leakage current and the breakdown strength of the seasoning layer, may be drastically improved by utilizing a carefully tailored ratio of the oxygen-containing precursor to the silicon-containing precursor. Thus, in embodiments, the deposition precursors may be flowed into the processing region of the chamber at flow rate ratio of the oxygen-containing precursor to the silicon-containing precursors of greater than or about 1:1, greater than or about 1.1:1, greater than or about 1.2:1, greater than or about 1.3:1, greater than or about 1.4:1, greater than or about 1.5:1, greater than or about 1.6:1, greater than or about 1.7:1, greater than or about 1.8:1, greater than or about 1.9:1, greater than or about 2:1, or more up to less than or about 10:1, less than or about 9:1, less than or about 8:1, less than or about 7:1, less than or about 6:1, less than or about 5:1, less than or about 4:1, less than or about 3:1, less than or about 2.5:1, as well as any ranges or values therebetween.

Moreover, the present technology has surprisingly found that the temperature at which deposition occurs can significantly influence the quality, properties, and uniformity of the deposited layer or layers. Thus, in embodiments, by carefully controlling the deposition temperature, alone or in combination with the precursor ratios discussed above, quality of the seasoning layer, and therefore the leakage current and the breakdown strength of the seasoning layer, may be drastically improved. In embodiments of the present technology, the one or more deposition precursors are flowed into a semiconductor processing chamber where the chamber, the component, the pedestal, or a combination thereof, are held at a temperature of greater than or about 350° C., greater than or about 360° C., greater than or about 370° C., greater than or about 380° C., greater than or about 390° C., greater than or about 400° C., greater than or about 410° C., greater than or about 420° C., greater than or about 430° C., greater than or about 440° C., greater than or about 450° C., greater than or about 460° C., greater than or about 470 greater than or about 480° C., greater than or about 490° C., greater than or about 500° C., greater than or about 510° C., greater than or about 520° C., greater than or about 530° C., greater than or about 540° C., greater than or about 550° C., greater than or about 560° C., greater than or about 570° C., greater than or about 580° C., greater than or about 590° C., greater than or about 600° C., greater than or about 610° C., greater than or about 620° C., greater than or about 630° C., greater than or about 640° C., greater than or about 650° C., greater than or about 660° C., greater than or about 670° C., greater than or about 680° C., greater than or about 690° C., greater than or about 700° C., or greater, or such as less than or about 1000° C., less than or about 900° C., less than or about 800° C., less than or about 750° C., or any ranges or values therebetween.

In addition, the present technology has surprisingly found that by increasing the thickness of the seasoning layer, improved electrical properties may be achieved while also preventing migration of metal during processing. Without wishing to be bound by theory, thicker seasoning layer may increase the distance that an electric field must traverse to cause a breakdown, rending it more difficult for the electric field to reach the critical threshold required for dielectric breakdown. As a result, the seasoning layer may withstand higher voltages before breaking down or exhibiting unacceptably high leakage current and may also exhibit improved resistance to metal migration. Thus, in embodiments of the present technology, a seasoning layer 510 may be formed at a thickness of greater than 0.5 μm, greater than or about 0.6 μm, greater than or about 0.8 μm, greater than or about 1 μm, greater than or about 1.2 μm, greater than or about 1.4 μm, greater than or about 1.6 μm, greater than or about 1.8 μm, greater than or about 2.0 μm, greater than or about 2.2 μm, greater than or about 2.4 μm, greater than or about 2.6 μm, greater than or about 2.8 μm, greater than or about 3.0 μm, greater than or about 3.2 μm, greater than or about 3.4 μm, greater than or about 3.6 μm, greater than or about 3.8 μm, greater than or about 4.0 μm, greater than or about 4.2 μm, greater than or about 4.4 μm, greater than or about 4.6 μm, greater than or about 4.8 μm, greater than or about 5.0 μm, greater than or about 5.2 μm, greater than or about 5.4 μm, greater than or about 5.6 μm, greater than or about 5.8 μm, greater than or about 6.0 μm, greater than or about 6.2 μm, greater than or about 6.4 μm, greater than or about 6.6 μm, greater than or about 6.8 μm, greater than or about 7.0 μm, greater than or about 7.2 μm, greater than or about 7.4 μm, greater than or about 7.6 μm, greater than or about 7.8 μm, greater than or about 8.0 μm, or greater, or such as less than or about 15.0 μm, less than or about 12.5 μm, less than or about 10 μm, less than or about 7.5 μm, or any ranges or values therebetween.

In embodiments, the deposition of the one or more seasoning layers at operation 410 may include a plasma-enhanced chemical vapor deposition (PECVD), atomic layer deposition (ALD), physical vapor deposition (PVD), chemical vapor deposition (CVD), or combinations thereof. However, in embodiments, it may be desired to utilize one or more plasma processes, such as PECVD. In embodiments, deposition may include generating a plasma from the deposition precursors and forming one or more seasoning layers 510 from the plasma effluents of the deposition precursors, as illustrated in FIG. 5B.

For instance, in embodiments, the precursors delivered to the processing region, such as the silicon-containing precursor alone or in combination with the oxygen-containing precursor and any carrier gasses, may be used to generate a plasma within the processing region of the semiconductor processing chamber. The plasma may be generated by, for example, providing RF power to the faceplate to generate a plasma within processing region 220, although any other processing chamber capable of producing plasma may similarly be used. In embodiments, the plasma may be generated at a frequency greater than or about 13 MHz, greater than or about 13.5 MHz, greater than or about 14 MHz, greater than or about 14.5 MHz, greater than or about 15 MHz, or any ranges or values therebetween. Although lower frequency may be used, in some embodiments the higher frequency plasma generation may densify the plasma and, therefore, densify the deposited material, unlike lower plasma frequency operations. Accordingly, the plasma may be generated at a frequency greater than or about 17 MHz, greater than or about 19 MHz, greater than or about 21 MHz, greater than or about 23 MHz, greater than or about 25 MHz, greater than or about 27 MHz, or higher.

Additionally, a plasma power may be maintained at less than or about 1000 W while generating plasma effluents of the silicon-containing precursor and plasma effluents of the oxygen-containing precursor. Accordingly, the plasma power may be maintained at less than or about 900 W, less than or about 800 W, less than or about 700 W, less than or about 600 W, less than or about 500 W, less than or about 450 W, less than or about 400 W, less than or about 350 W, less than or about 300 W, less than or about 250 W, less than or about 200 W, less than or about 150 W, less than or about 100 W, or less. However, in embodiments, a plasma power of greater than 1000 W may be utilized, such as greater than or about 1100 W, greater than or about 1200 W, greater than or about 1300 W, greater than or about 1400 W, greater than or about 1500 W, greater than or about 1600 W, greater than or about 1700 W, greater than or about 1800 W, greater than or about 1900 W, greater than or about 2000 W, or any ranges or values therebetween.

During the deposition of the silicon-containing material, the semiconductor processing chamber may be maintained at any pressure suitable for forming silicon-containing material. For example, a pressure within the semiconductor processing chamber is maintained at less than or about 30 Torr, and in some embodiments may be maintained at a pressure that is less than or about 28 Torr, less than or about 26 Torr, less than or about 24 Torr, less than or about 22 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, or less.

As the deposition precursors are flowed into the semiconductor processing chamber and contact the chamber component, a high-quality seasoning layer 510 is formed on a semiconductor processing component 500, as illustrated in FIG. 5B. Namely, the present technology has found that by forming one or more seasoning layers according to the disclosure herein, a breakdown voltage of the one or more seasoning layers may be greater than or about 2 MV/cm, greater than or about 2.5 MV/cm, greater than or about 3 MV/cm, greater than or about 3.5 MV/cm, greater than or about 4 MV/cm, greater than or about 4.5 MV/cm, greater than or about 5 MV/cm, greater than or about 5.5 MV/cm, greater than or about 6 MV/cm, greater than or about 6.5 MV/cm, greater than or about 7 MV/cm, greater than or about 7.5 MV/cm, greater than or about 8 MV/cm, greater than or about 8.5 MV/cm, greater than or about 9 MV/cm, greater than or about 9.5 MV/cm, greater than or about 10 MV/cm, greater than or about 10.5 MV/cm, greater than or about 11 MV/cm, greater than or about 11.5 MV/cm, or such as less than or about 15 MV/cm, less than or about 14 MV/cm, less than or about 13 MV/cm, less than or about 12 MV/cm, less than or about 11 MV/cm, less than or about 1 MV/cm, or any ranges or values therebetween. In addition, the breakdown voltage of the one or more seasoning layers may be achieved at relatively high current, such as greater than or about 1×10⁻⁸ A/cm², greater than or about 1×10⁻⁷ A/cm², greater than or about 1×10⁻⁶ A/cm², greater than or about 1×10⁻⁵ A/cm², greater than or about 1×10⁻⁴ A/cm², greater than or about 1×10⁻³ A/cm², or any ranges or values therebetween.

Furthermore, as discussed above the one or more seasoning layers may have improved quality over prior seasoning layers. For instance, seasoning layers according to the present technology may exhibit a modulus of greater than or about 50 GPA, greater than or about 52 GPA, greater than or about 54 GPA, greater than or about 56 GPA, greater than or about 58 GPA, greater than or about 60 GPA, greater than or about 62 GPA, greater than or about 64 GPA, greater than or about 66 GPA, greater than or about 68 GPA, greater than or about 70, greater than or about 72 GPA, greater than or about 74 GPA, greater than or about 76 GPA, greater than or about 78 GPA, greater than or about 80 GPA, greater than or about 82 GPA, greater than or about 84 GPA, greater than or about 86 GPA, greater than or about 88 GPA, greater than or about 90 GPA, greater than or about 92 GPA, greater than or about 94 GPA, greater than or about 96 GPA, greater than or about 98 GPA, greater than or about 100 GPA, greater than or about 102 GPA, greater than or about 104 GPA, up to about 105 GPA, or any ranges or values therebetween.

Additionally or alternatively, seasoning layers according to the present technology may exhibit a hardness of greater than or about 5 GPA, greater than or about 6 GPA, greater than or about 8 GPA, greater than or about 10 GPA, greater than or about 12 GPA, greater than or about 14 GPA, greater than or about 16 GPA, greater than or about 18 GPA, greater than or about 20 GPA, greater than or about 22 GPA, greater than or about 24 GPA, greater than or about 26 GPA, greater than or about 28 GPA, greater than or about 30 Gpa, or any ranges or values therebetween.

Furthermore, seasoning layers according to the present technology may exhibit less than 1 wt. % impurities, such as carbon or hydrogen, such as less than or about 0.95 wt. %, less than or about 0.9 wt. %, less than or about 0.85 wt. %, less than or about 0.8 wt. %, less than or about 0.75 wt. %, less than or about 0.7 wt. %, less than or about 0.65 wt. %, less than or about 0.6 wt. %, less than or about 0.55 wt. %, less than or about 0.5 wt. %, based upon the weight of the one or more seasoning layers, or any ranges or values therebetween.

While thus far, the seasoning layer 510 has been illustrated on being formed on a top surface 520 of component 500, which may be opposed to a bottom surface 525, it should be clear that the present technology also contemplates forming one or more seasoning layers 510 on multiple surfaces of the one or more components, as illustrated in FIG. 5C. For instance, in embodiments, the deposition process of operations 405 and 410 may season or coat one or more exposed surfaces of the component, or such as any exposed surfaces, in embodiments. In some embodiments, the process may also be a line-of-sight process, such that only surfaces facing the plasma source are coated. Nonetheless, as illustrated in FIG. 5C, it should be understood that one or more additional surfaces, such as side surface 530 of component 500.

After the seasoning layer 510 has been formed on the semiconductor processing component 500, a substrate may be placed on or adjacent to the seasoned processing chamber component 500, at operation 415. In some embodiments the semiconductor component is an electrostatic chuck. Thus, in embodiments, electrostatic chucking may be utilized to chuck a substrate during processing, at operation 420. As discussed above, in embodiments, the present technology may provide a seasoning layer that exhibits excellent electrical properties, and therefore allows for the use of high chucking voltages with reduced or eliminated risk of arcing. Thus, in embodiments, the electrostatic chuck of the present technology may be well suited to provide a chucking voltage of greater than or about 500 V, greater than or about 550 V, greater than or about 600 V, greater than or about 650 V, greater than or about 700 V, greater than or about 750 V, greater than or about 800 V, greater than or about 850 V, greater than or about 900 V, greater than or about 950 V, greater than or about 1.0 kV, greater than or about 1.05 kV, greater than or about 1.1 kV, greater than or about 1.15 kV, greater than or about 1.2 kV, greater than or about 1.25 kV, greater than or about 1.3 kV, greater than or about 1.35 kV, greater than or about 1.4 kV, greater than or about 1.45 kV or any ranges or values therebetween, can be applied to the substrate with reduced arcing.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of seasoning a semiconductor processing chamber component comprising:
flowing one or more deposition precursors at a deposition temperature into a substrate processing region of a semiconductor processing chamber housing the semiconductor processing chamber component, wherein the substrate processing region includes an electrostatic chuck and wherein the one or more deposition precursors are generally free of a nitride precursor; and
depositing at least a first seasoning layer on the semiconductor processing chamber component;
wherein the at least the first seasoning layer comprises a thickness of greater than 0.5 μm.

2. The method of claim 1, wherein the semiconductor processing chamber component comprises an electrostatic chuck.

3. The method of claim 1, wherein the one or more deposition precursors comprise a silicon-containing precursor, the silicon-containing precursor comprising silane (SiH₄), disilane (Si₂H₆), trisilane (Si₃H₈), silicon tetrachloride (SiCl₄), tetraethyl orthosilicate (TEOS), or combinations thereof.

4. The method of claim 3, wherein the one or more deposition precursors comprise an oxygen-containing precursor, the oxygen containing precursor comprising molecular oxygen (O₂), ozone (O₃), or combinations thereof.

5. The method of claim 4, wherein the one or more deposition precursors comprise tetraethyl orthosilicate and molecular oxygen.

6. The method of claim 1, wherein one or more deposition precursors comprises a silicon-containing precursor and an oxygen-containing precursor, wherein a ratio of the oxygen-containing precursor to the silicon-containing precursor is greater than or about 1:1.

7. The semiconductor processing method of claim 1, wherein the at least a first seasoning layer comprises silicon oxide, and comprises a thickness greater than or about 1 micrometer.

8. The semiconductor processing method of claim 7, wherein the seasoning layer comprises a thickness greater than or about 3.6 micrometers.

9. The semiconductor processing method of claim 1, wherein the deposition temperature is greater than or about 350° C.

10. The semiconductor processing method of claim 9, wherein the deposition temperature is greater than 550° C.

11. A substrate support assembly comprising:
an electrostatic chuck, wherein at least a portion of the electrostatic chuck comprises a seasoning layer;
a support stem coupled to the electrostatic chuck; and
an electrode embedded within the electrostatic chuck between a substrate support surface and the support stem;
wherein the seasoning layer comprises a thickness greater than 0.5 micrometers and is free of nitride or nitride containing materials.

12. The substrate support assembly of claim 11, wherein the seasoning layer comprises silicon oxide, and comprises a thickness greater than or about 1 micrometer.

13. The substrate support assembly of claim 12, wherein the seasoning layer comprises a thickness greater than or about 3.6 micrometers.

14. The substrate support assembly of claim 11, wherein the support substrate further comprises a heater embedded within the electrostatic chuck.

15. The substrate support assembly of claim 11, wherein the seasoning layer comprises a modulus of greater than or about 50 GPA, a hardness of greater than or about 5 GPA, less than 1 wt. % impurities, or a combination thereof.

16. A semiconductor processing method comprising:
contacting a semiconductor substrate with an electrostatic chuck in a substrate processing region of a semiconductor processing chamber, wherein the electrostatic chuck has been seasoned with a seasoning layer, wherein the seasoning layer is generally free of nitride or nitride containing materials;
applying a chucking voltage to the semiconductor substrate of greater than or about 1.2 kV, and;
depositing two or more layers on the chucked substrate, wherein the greater than two layers comprises one or more alternating pairs of oxide and nitride material.

17. The semiconductor processing method of claim 16, wherein the two or more layers comprise an oxide-nitride (ON) stack.

18. The semiconductor processing method of claim 16, wherein the two or more layers comprise greater than or about 100 layers.

19. The semiconductor processing method of claim 16, wherein the chucking voltage is greater than or about 1.4 kV.

20. The semiconductor processing method of claim 16, wherein the seasoning layer comprises a modulus of greater than or about 50 GPA, a hardness of greater than or about 5 GPA, less than 1 wt. % impurities, or a combination thereof.
